(19) United States
(12) Patent Application Publication
(10) Pub. No.: US 2006/0249792 A1
(43) Pub. Date: Nov. 9, 2006

(54) Electrostatic discharge protection circuit and integrated circuit having the same

(75) Inventors: Young-Chul Kim, Yongin-si (KR); Jong-Sung Jeon, Goyang-si (KR); Won-Hyung Pong, Suwon-si (KR)

Correspondence Address: MILLS & ONELLO LLP, ELEVEN BEACON STREET, SUITE 605, BOSTON, MA, 02108, US

(73) Assignee: Samsung Electronics Co., Ltd.

(21) Appl. No.: 11/415,040

(22) Filed: May 1, 2006

(30) Foreign Application Priority Data
May 4, 2005 (KR) 10-2005-0037386

(51) Int. Cl. H01L 23/62

(52) U.S. Cl. 257/355

(57) ABSTRACT

An electrostatic discharge (ESD) protection circuit has a low trigger voltage. The ESD protection circuit is coupled between two rails. The ESD protection circuit includes a connection load and a second transistor. The connection load turns on a first transistor when an ESD event occurs, and the second transistor generates a current due to an avalanche breakdown. A latch-up current is generated due to the avalanche breakdown.

### CLAIM FOR PRIORITY

This application claims priority to Korean Patent Application No. 2005-37386 filed on May 4, 2005 in the Korean Intellectual Property Office (KIPO), the contents of which are herein incorporated by reference in its entirety.

### BACKGROUND OF THE INVENTION

1. Field of the Invention

The present invention relates to a circuit for protecting a sensitive electric device such as an integrated circuit, and more particularly to an electrostatic discharge protection circuit and integrated circuit having the same for preventing an overvoltage of a sensitive electric device, for example, in case of electrostatic discharge (ESD).

2. Description of the Related Art

Integration density of an integrated circuit has been increased according to improvement of semiconductor fabrication technology. According to enhancement of the integrity of the integrated circuit, the necessity of protecting the integrated circuit from electrostatic discharge (ESD) increases.

A Gate-Grounded Metal-Oxide Semiconductor (GGMOS) is used as an ESD protection circuit. The GGMOS is implemented as a MOS, which has a drain connected to a Vdd terminal for supplying a source voltage to the protected integrated circuit, a source connected to a Vss terminal for grounding the protected integrated circuit, and a gate connected to the drain thereof.

The MOS connected between the Vdd terminal and the Vss terminal operates just like a reverse-biased diode, so that the MOS is turned off when a normal voltage is applied to the protected integrated circuit. However, when a voltage of the Vss terminal is suddenly higher than a voltage of the Vdd terminal, the MOS is turned on and a positive charge of the Vss terminal (or a negative charge of the Vdd terminal) is discharged to the Vdd terminal (or the Vss terminal) such that the integrated circuit can be protected.

When the voltage of the Vdd terminal rises suddenly or the voltage of the Vss terminal drops suddenly, a breakdown is generated at the MOS due to high reverse bias, so that the positive charge of the Vdd terminal (or the negative charge of the Vss terminal) is discharged to the Vss terminal (The Vdd terminal). The GGMOS used as the ESD protection circuit has a low trigger voltage, but has low discharging efficiency because the GGMOS basically has operational characteristics of the MOS.

Furthermore, a thyristor or a Silicon Controlled Rectifier (SCR) is designed as a protection device for the purpose of efficient ESD protection. However, the initial SCR has a high trigger voltage such that the initial SCR does not operate at a voltage lower than or equal to the trigger voltage. Research for designing a Low Voltage Trigger SCR (LVTSCR) for dropping the trigger voltage of the SCR has been performed. U.S. Pat. No. 6,939,616 discloses the LVTSCR. The LVTSCR disclosed in U.S. Pat. No. 6,939,616 is shown in FIG. 1 and FIG. 2.

FIG. 1 is a cross sectional view illustrating a conventional electrostatic discharge (ESD) protection circuit, and FIG. 2 is a circuit diagram illustrating an equivalent circuit of the ESD protection circuit of FIG. 1.

Referring to FIG. 1, an ESD protection circuit 31 is formed in a substrate 30 lightly doped with P-type dopants. An N-well 32 lightly doped with N-type dopants is formed in the substrate 30. A region 34 heavily doped with the N-type dopants and a region 36 heavily doped with the P-type dopants are formed in the N-well 32. Two regions 34 and 36 are connected to a pad 38 of an integrated circuit having the ESD protection circuit 31. A region 42 heavily doped with the N-type dopants is formed at a boundary region between the N-well 32 and the substrate 30. One terminal of a resistor 44 is connected to the pad 38 and the other terminal thereof is connected to the region 42. A region 40 is spaced apart from the N-well 32 and is connected to a ground or a reference voltage.

Referring to FIGS. 1 and 2, a transistor 52 is constituted by the region 36 provided as an emitter, the region 32 provided as a base and the substrate 30 provided as a collector. A transistor 54 is constituted by the region 32 provided as a collector, the substrate 30 provided as a base and the region 40 provided as an emitter. A transistor 60 is constituted by the region 42 provided as a collector, the substrate 30 provided as a base and the region 40 provided as an emitter.

A resistor 56 corresponds to a resistive component caused by the region 34 heavily doped with the N-type dopants, the region 36 heavily doped with the P-type dopants and the N-well 32 lightly doped. A resistor 58 corresponds to a resistance component of the substrate 30 for the ground. A resistor 46 denotes a resistance component of the N-well 32 lightly doped with the N-type dopants. A resistor 44 is connected between the emitter of the transistor 52 and the collector of the transistor 60.

The transistor 60 is a low avalanche critical trigger transistor. Because of a junction between the region 42 doped with N-type dopants and the substrate 30 doped with P-type dopants, the transistor 60 reaches an avalanche condition at a voltage lower than that of the transistor 54. When the transistor 60 is turned on, the transistor 60 provides a bias current to the base of the transistor 54, so that the transistor 54 provides a base current to the transistor 52, and the transistor 52 is turned on. Hence, the ESD protection circuit 31 operates until the transistors 52 and 54 are turned off owing to a deficiency of a current flowing through the resistor 56 and the resistor 58.

As mentioned above, the LVTSCR has advantages in that the LVTSCR operates at a low trigger voltage and has characteristics of the initial SCR that discharges more current per area. Regardless of the advantages, the LVTSCR has disadvantages as follows.

When an electrical overstress (EOS) of an overvoltage pulse is applied to the operating LVTSCR, a latch-up may be generated. Thus, it is required to prevent the latch-up due to the EOS during the design of the LVTSCR. Furthermore, an additional process is required so as to manufacture the LVTSCR. The additional process is a process for forming an N+ or P+ region 42 at an edge of the N-well 32 shown in FIG. 1. The additional process increases a cost of manufacturing the integrated circuit. Furthermore, a temperature may increase owing to an intensive electric field near the region 42.

As described above, the conventional ESD protection circuit has some disadvantages. Thus, there is required an ESD protection circuit that is able to operate at a low trigger voltage, is resistant to an EOS surge voltage, and the number of additional processes may be reduced.

### SUMMARY OF THE INVENTION

Accordingly, the present invention is provided to substantially obviate one or more problems due to limitations and disadvantages of the related art.

Example embodiments of the present invention provide an electrostatic discharge (ESD) protection circuit having a low trigger voltage and robust characteristics for a latch-up.

Example embodiments of the present invention also provide an integrated circuit including the ESD protection circuit having the low trigger voltage and the robust characteristics for the latch-up.

According to a first aspect, the present invention is directed to an ESD protection circuit coupled between a first rail and a second rail. The ESD protection circuit includes: a substrate lightly doped with a first impurity of a first conduction type; a first region lightly doped with a second impurity of a second conduction type, and formed at a first surface portion of the substrate; a second region heavily doped with a third impurity of the second conduction type, formed at a second surface portion in the first region, and coupled to the first rail; a third region heavily doped with a fourth impurity of the first conduction type, formed at a third surface portion in the first region, and spaced apart from the second region; a fourth region heavily doped with the fourth impurity of the second conduction type, formed at a fourth surface portion in the first region, spaced apart from the third region, and coupled to the first rail; a fifth region heavily doped with a fifth impurity of the second conduction type, formed at a fifth surface portion of the substrate, spaced apart from the first region, and coupled to the second rail; a sixth region heavily doped with the fifth impurity of the second conduction type, formed at a sixth surface portion of the substrate, spaced apart from the fifth region, and coupled to the third region; a seventh region heavily doped with a sixth impurity of the first conduction type, formed at a seventh surface portion of the substrate, spaced apart from the sixth region, and coupled to the second node; a first insulating layer formed on a surface of the substrate between the third region and the fourth region; a second insulating layer formed on the surface of the surface between the fifth region and the sixth region; a first gate formed on the first insulating layer; a second gate formed on the second insulating layer, and coupled to the first gate; and a connection load having a first terminal coupled to the first rail and a second terminal coupled to the first gate.

According to another aspect, the invention is directed to an ESD protection circuit coupled between a first rail and a second rail. The ESD protection circuit includes: a substrate lightly doped with a first impurity of a first conduction type; a first region lightly doped with a second impurity of a second conduction type, and formed at a first surface portion of the substrate; a second region heavily doped with a third impurity of the second conduction type, formed at a second surface portion in the first region, and coupled to the first rail; a third region heavily doped with a fourth impurity of the first conduction type, formed at a third surface portion in the first region, and spaced apart from the second region; a fourth region heavily doped with the fourth impurity of the first conduction type, formed at a fourth surface portion in the first region, spaced apart from the third region, and coupled to the first rail; a fifth region heavily doped with a fifth impurity of the second conduction type, formed at a fifth surface portion of the substrate, spaced apart from the first region, and coupled to the second rail; a sixth region heavily doped with the fifth impurity of the second conduction type, formed at a sixth surface portion of the substrate, spaced apart from the fifth region, and coupled to the third region; a seventh region heavily doped with a sixth impurity of the first conduction type, formed at a seventh surface portion of the substrate, spaced apart from the sixth region, and coupled to the second rail; a first insulating layer formed on a surface of the substrate between the third region and the fourth region; a second insulating layer formed on the surface of the substrate between the fifth region and the sixth region; a first gate formed on the first insulating layer; a second gate formed on the second insulating layer, and coupled to the first gate; and a connection load having a first terminal coupled to the second rail and a second terminal coupled to the first gate.

According to another aspect, the present invention is directed to an integrated circuit, which includes: a protected circuit; a first rail coupled to a first terminal of the protected circuit; a second rail coupled to a second terminal of the protected circuit; a substrate lightly doped with a first impurity of a first conduction type; a first region lightly doped with a second impurity of a second conduction type, and formed at a first surface portion of the substrate; a second region heavily doped with a third impurity of the second conduction type, formed at a second surface portion in the first region, and coupled to the first rail; a third region heavily doped with a fourth impurity of the first conduction type, formed at a third surface portion in the first region, and spaced apart from the second region; a fourth region heavily doped with the fourth impurity of the first conduction type, formed at a fourth surface portion in the first region, spaced apart from the third region, and coupled to the first rail; a fifth region heavily doped with a fifth impurity of the second conduction type, formed at a fifth surface portion of the substrate, spaced apart from the first region, and coupled to the second rail; a sixth region heavily doped with the fifth impurity of the second conduction type, formed at a sixth surface portion of the substrate, spaced apart from the fifth region, and coupled to the third region; a seventh region heavily doped with a sixth impurity of the first conduction type, formed at a seventh surface portion of the substrate, spaced apart from the sixth region, and coupled to the second rail; a first insulating layer formed on a surface of the substrate between the third region and the fourth region; a second insulating layer formed on the surface of the substrate between the fifth region and the sixth region; a first gate formed on the first insulating layer; a second gate formed on the second insulating layer, and coupled to the first gate; and a connection load having a first terminal coupled to the first rail and a second terminal coupled to the first gate.

According to another aspect, the present invention is directed to an integrated circuit, which includes: a protected circuit; a first rail coupled to a first terminal of the protected circuit; a second rail coupled to a second terminal of the protected circuit; a substrate lightly doped with a first impurity of a first conduction type; a first region lightly doped with a second impurity of a second conduction type, and formed at a first surface portion of the substrate; a second region heavily doped with a third impurity of the second conduction type, formed at a second surface portion in the first region, and coupled to the first rail; a third region heavily doped with a fourth impurity of the first conduction type, formed at a third surface portion in the first region, and spaced apart from the second region; a fourth region heavily doped with the fourth impurity of the first conduction type, formed at a fourth surface portion in the first region, spaced apart from the third region, and coupled to the first rail; a fifth region heavily doped with a fifth impurity of the second conduction type, formed at a fifth surface portion of the substrate, and coupled to the second rail; a sixth region heavily doped with the fifth impurity of the second conduction type, formed at a sixth surface portion of the substrate, spaced apart from the fifth region, and coupled to the third region; a seventh region heavily doped with a sixth impurity of the first conduction type, formed at a seventh surface portion of the substrate, spaced apart from the sixth region, and coupled to the second rail; a first insulating layer formed on a surface of the substrate between the third region and the fourth region; a second insulating layer formed on the surface of the substrate between the fifth region and the sixth region; a first gate formed on the first insulating layer; a second gate formed on the second insulating layer, and coupled to the first gate; and a connection load having a first terminal coupled to the second rail and a second terminal coupled to the first gate.

According to another aspect, the present invention is directed to an ESD protection circuit coupled between a first rail and a second rail, which includes: a first transistor of a first type, the first transistor having a source coupled to the first rail; a second transistor of a second type, the second transistor having a source coupled to the second rail, a drain coupled to a drain of the first transistor, and a gate coupled to a gate of the first transistor; and a connection load having a first terminal coupled to the first rail and a second terminal coupled to the gate of the first transistor.

According to another aspect, the present invention is directed to an ESD protection circuit coupled to a first rail and a second rail, which includes: a first transistor of a first type, the first transistor having a source coupled to the first rail; a second transistor of a second type, the second transistor having a source coupled to the second rail, a drain coupled to a drain of the first transistor, and a gate coupled to a gate of the first transistor; and a connection load having a first terminal coupled to the second rail and a second terminal coupled to the gate of the second transistor.

According to another aspect, the present invention is directed to an integrated circuit, which includes: a protected circuit; a first rail coupled to a first terminal of the protected circuit; a second rail coupled to a second terminal of the protected circuit; a first transistor of a first type, the first transistor having a source coupled to the first rail; a second transistor of a second type, the first transistor having a source coupled to the second rail, a drain coupled to a drain of the first transistor, and a gate coupled to a gate of the first transistor; and a connection load having a first terminal coupled to the first rail and a second terminal coupled to the gate of the first transistor.

According to another aspect, the present invention is directed to an integrated circuit, which includes: a protected circuit; a first rail coupled to a first terminal of the protected circuit; a second rail coupled to a second terminal of the protected circuit; a first transistor of a first type, the first transistor having a source coupled to the first rail; a second transistor of a second type, the second transistor having a source coupled to the second rail, a drain coupled to a drain of the first transistor, and a gate coupled to a gate of the first transistor; and a connection load having a first terminal coupled to the second rail and a second terminal coupled to the gate of the first transistor.

### BRIEF DESCRIPTION OF THE DRAWINGS

The foregoing and other objects, features and advantages of the invention will be apparent from the more particular description of preferred aspects of the invention, as illustrated in the accompanying drawings in which like reference characters refer to the same parts throughout the different views. The drawings are not necessarily to scale, emphasis instead being placed upon illustrating the principles of the invention. In the drawings, the thickness of layers and regions are exaggerated for clarity. FIG. 1 is a cross sectional view illustrating a conventional electrostatic discharge (ESD) protection circuit.

FIG. 2 is a circuit diagram illustrating an equivalent circuit of the ESD protection circuit of FIG. 1.

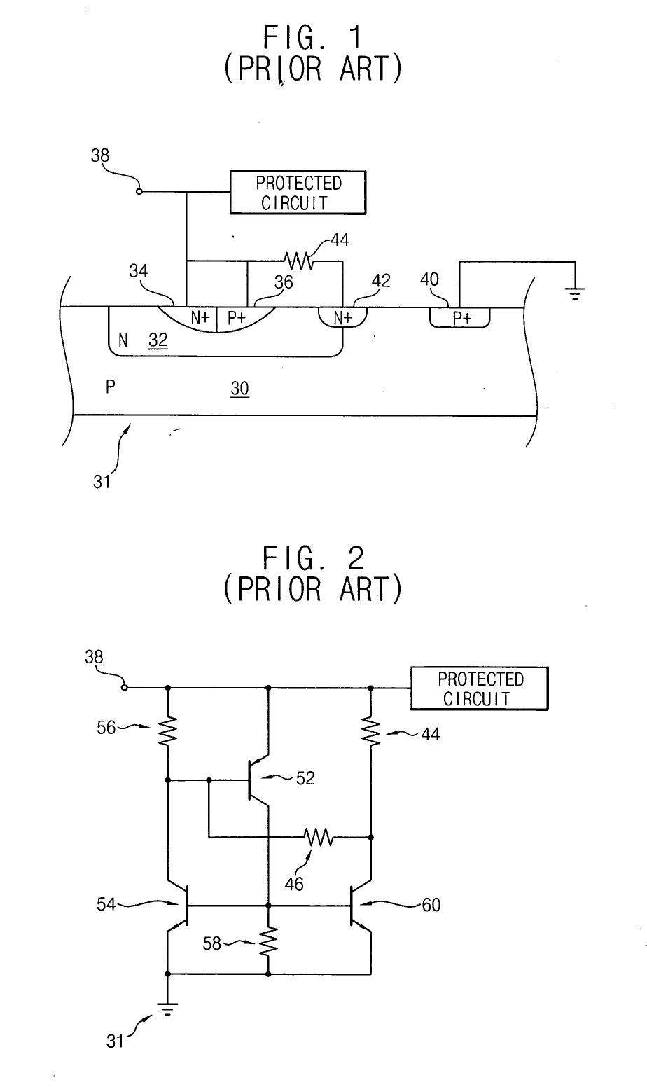

FIG. 3 is a circuit diagram illustrating an ESD protection circuit according to an example embodiment of the present invention.

FIG. 4 is a schematic view illustrating an operation of the ESD protection circuit of FIG. 3.

FIG. 5 is a cross sectional view illustrating an integrated circuit that implements the ESD protection circuit of FIG. 3.

FIG. 6 is a cross sectional view illustrating an integrated circuit that implements the ESD protection circuit of FIG. 3.

FIGS. 7A and 7B are schematic views illustrating a simulation result of the operation of the ESD protection circuit of FIG. 3.

FIG. 8 is a circuit diagram illustrating an ESD protection circuit according to another example embodiment of the present invention.

FIG. 9 is a block diagram illustrating an integrated circuit that is protected by an ESD protection circuit according to an example embodiment of the present invention.

### DESCRIPTION OF THE EXAMPLE EMBODIMENTS

Example embodiments of the present invention are disclosed herein. However, specific structural and functional details disclosed herein are merely representative for purposes of describing example embodiments of the present invention. Thus, example embodiments of the present invention may be embodied in many alternate forms and should not be construed as limited to example embodiments of the present invention set forth herein.

Accordingly, while the invention is susceptible to various modifications and alternative forms, specific embodiments thereof are shown by way of example in the drawings and will herein be described in detail. It should be understood, however, that there is no intent to limit the invention to the particular forms disclosed, but on the contrary, the invention is to cover all modifications, equivalents, and alternatives falling within the spirit and scope of the invention. Like numbers refer to like elements throughout the description of the figures.

It will be understood that, although the terms first, second, etc. may be used herein to describe various elements, these elements should not be limited by these terms. These terms are used to distinguish one element from another. For example, a first element could be termed a second element, and, similarly, a second element could be termed a first element, without departing from the scope of the present invention. As used herein, the term “and/or” includes any and all combinations of one or more of the associated listed items.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between”, “adjacent” versus “directly adjacent”, etc.).

The terminology used herein is for the purpose of describing particular embodiments and is not intended to be limiting of the invention. As used herein, the singular forms “a”, “an” and “the” are intended to include the plural forms as well, unless the context clearly indicates otherwise. It will be further understood that the terms “comprises”, “comprising”, “includes” and/or “including”, when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

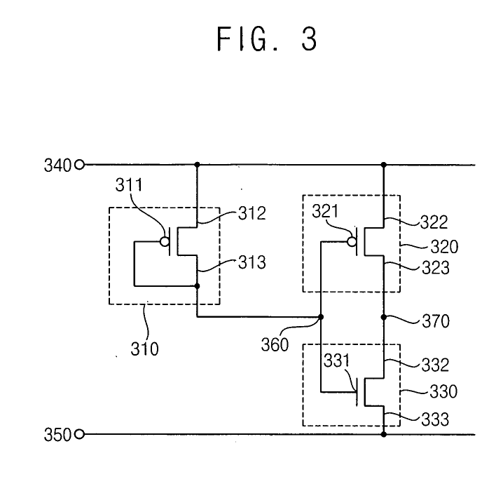

FIG. 3 is a circuit diagram illustrating an electrostatic discharge (ESD) protection circuit according to an embodiment of the present invention.

Referring to FIG. 3, the ESD protection circuit is connected between a first rail 340 and a second rail 350, and has a connection load 310 and two transistors 320 and 330.

The first rail 340 and the second rail 350 may be a Vdd pad or a Vss pad that supplies a source voltage to an integrated circuit such as a memory circuit, a microprocessor or a logic circuit, or alternatively may be a data in/out pad, which are easily damaged by ESD.

The first transistor 320 and the second transistor 330 constitute a CMOS inverter. A source 322 of the first transistor 320 is connected to the first rail 340 and a source 333 of the second transistor 330 is connected to the second rail 350. Drains 323 and 332 of the two transistors 320 and 330 are connected to each other and gates 321 and 331 of the two transistors 320 and 330 are connected to each other.

The connection load 310 transmits a voltage of the first rail 340 to a connection node 360 to which the gates 321 and 331 of two transistors 320 and 330 are commonly connected. The connection load 310 may be a resistor or a MOS transistor. When the connection load 310 is a MOS transistor, charged device model characteristics are enhanced. The connection load 310 shown in FIG. 3 is a diode-connected PMOS transistor, of which a source is connected to the first rail 340 and a gate is connected to a drain thereof such that the gate and the drain are commonly connected to the connection node 360.

Hereinafter, the first rail 340 is presumed to be the Vdd pad and the second rail Vss pad is presumed to be the Vss pad so as to describe the ESD protection circuit of FIG. 3.

When Vdd and Vss are supplied to the first rail 340 and the second rail 350, respectively, the connection load 310 is turned on such that the connection node 360 is pulled-up as a high level. When the connection node 360 has a high level, the first transistor 320 is turned off and the second transistor 330 is turned on. Due to the turned on second transistor 330, a connection node 370 has a low level. Furthermore, due to the turned-off first transistor 320, a current path between the first rail 340 and the second rail 350 is cut off. That is, when a normal source voltage is supplied to the first rail 340 and the second rail 350, the ESD protection circuit does not operate.

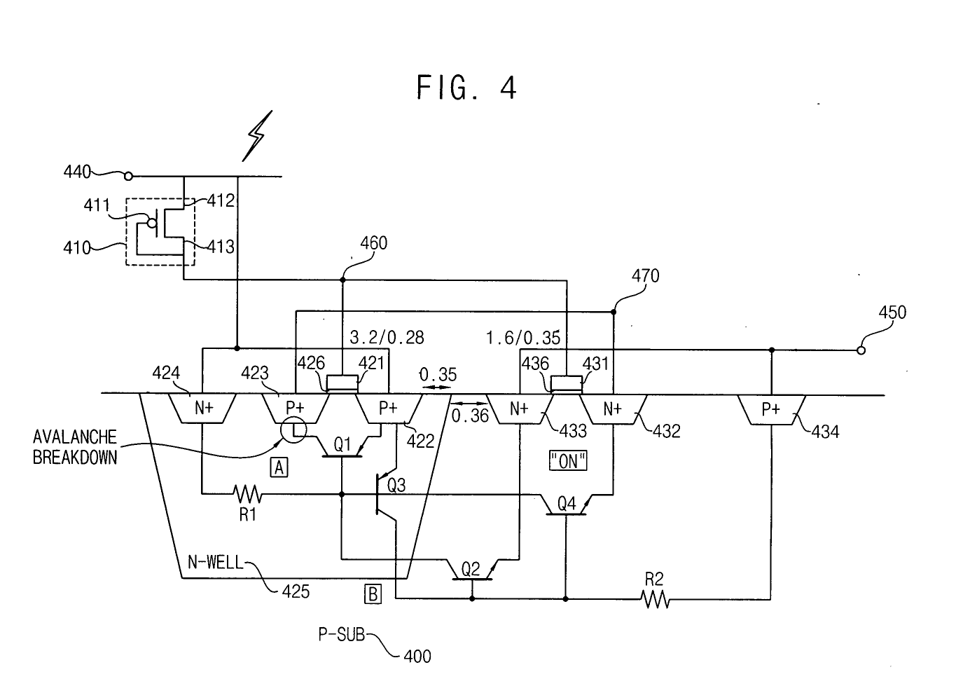

When an overvoltage due to an ESD is supplied to the first rail 340, the connection node 360 has a high level owing to the turned-on connection load 310. Hence, the second transistor 330 is turned on, the connection node 370 has a low level, and a high voltage is applied to the source 322 and the drain 323 of the first transistor 320 such that an avalanche breakdown occurs. Furthermore; when the first transistor 320 and the second transistor 330 are formed on a semiconductor substrate such that two transistors 320 and 330 have the configuration of the CMOS inverter, a parasitic Bipolar Junction Transistor (BJT) is formed. The parasitic BJTs of the CMOS inverter have substantially the same structure as that of an SCR, which will be described in connection with FIG. 4. A current generated from the first transistor 320 according to the avalanche breakdown flows through a base of the SCR that has the parasitic BJTs and have a PNPN structure, so that a latch-up occurs in the ESD protection circuit. The latch-up is terminated when applied electrostatic charges are discharged.

Furthermore, when a surge voltage having electrical overstress (EOS) occurs, the latch-up may be continuously maintained in the conventional LVTSCR regardless of a termination of the surge voltage having EOS. However, the latch-up does not occur in the CMOS inverter that was initially designed so as to solve the latch-up problem.

FIG. 4 is a schematic view illustrating operation of the ESD protection circuit of FIG. 3.

Referring FIG. 4, when an overvoltage owing to an electrostatic charge is applied to the first rail 440 and the second rail 450, the ESD protection circuit discharges the electrostatic charge and protects an integrated circuit. Hereinafter, the first rail 440 is presumed to be a Vdd pad and the second rail 450 is presumed to be a Vss pad.

The first transistor 320 of FIG. 3 may be implemented by a gate 421, an insulating layer 426 and regions 422 and 423. The second transistor 330 of FIG. 3 may be implemented by a gate 431, an insulating layer 436 and regions 432 and 433.

More particularly, the ESD protection circuit has a connection load 410 and two transistors having a structure of a CMOS inverter. The two transistors having the structure of the CMOS inverter are implemented as follows.

An N-well 425 lightly doped with N-type dopants is formed into a substrate 400 lightly doped with P-type dopants. A region 424 heavily doped with N-type dopants is formed from a surface of the substrate into the N-well 425. Heavily doped regions 422 and 423 with P-type dopants are formed from the surface of the substrate into the N-well 425.

Heavily doped regions 432 and 433 with N-type dopants and a heavily doped region 434 are formed from the surface of the surface into the substrate 400. The doped regions 432, 433 and 434 are spaced apart from the N-well 425.

The insulating layer 426 is formed on the surface of the substrate 400 and formed between the region 422 and the region 423. The gate 421 is formed on the insulating layer 426. The insulating layer 436 is formed on the surface of the substrate 400 and formed between the region 432 and the region 433. The gate 431 is formed on the insulating layer 436.

The regions 422 and 424 are connected to the first rail 440 and the regions 433 and 434 are connected to the second rail 450. The gates 421 and 431 are connected to one terminal of the connection load 410 and the other terminal of the connection load 410 is connected to the first rail 440. The region 423 is connected to the region 432. The term “connection” refers to two nodes or two terminals that are physically connected to each other or electrically connected to each other such that the two nodes or two terminals have equal voltage levels.

The region 424 allows a voltage of the N-well 425 to be substantially the same level as a voltage of the first rail 440, and a voltage of the substrate 400 to be substantially the same as a voltage of the second rail 450 due to the region 434.

As mentioned above, the CMOS inverter may form the SCR due to the parasitic BJT A PNP type BJT Q1 has an emitter provided by the region 422, a base provided by the N-well 425 and a collector provided by the region 423. Furthermore, a NPN type BJT Q2 has an emitter provided by the region 433, a base provided by the substrate 400 and a collector provided by the N-well 425. A PNP type BJT Q3 has an emitter provided by the region 422, a base provided by the N-well 425 and a collector provided by the substrate 400. A NPN type BJT Q4 has an emitter provided by the region 432, a base provided by the substrate 400 and a collector provided by the N-well 425. A resistor R1 is provided by the lightly doped N-well 425 and a resistor R2 is provided by the lightly doped substrate 400.

The region 422 is spaced apart from a boundary between the N-well 425 and the substrate 400 by a distance of L1 (e.g., 0.35), and the region 433 is spaced apart from the boundary between the N-well 425 and the substrate 400 by a distance of L2 (e.g., 0.36). The characteristics of the ESD protection circuit may be different according to the distances L1 and L2. Hence, the distances L1 and L2 may be controlled according to a condition required for a protected circuit, a design rule of manufacturing process of an integrated circuit, and a method of manufacturing the integrated circuit, etc.

When a positive ESD event occurs at the first rail 440, a channel under the gate 431 is formed between the region 432 and the region 433 according the voltage applied to the gate 431 via the connection load 410. That is, the second transistor 330 is turned on. When the channel is formed, the region 432 has substantially the same voltage as that of the region 433 to which the voltage of the second rail 450 is applied. Furthermore, the region 432 is electrically connected to the region 423 so that the regions 432 and 423 have substantially the same voltage. That is, the connection node 470 has substantially the same voltage as that of the second rail 450 and has a low level.

The overvoltage applied to the first rail 440 is transmitted to the region 424 and region 422. The overvoltage is applied to the N-well 425 via the regions 422 and 424. When the overvoltage is applied to the N-well 425, a strong electric field is generated near the N-well 425 and the region 423 such that the avalanche breakdown occurs. Electrons generated by the avalanche breakdown flow from a region near “A” to the region 424 through the N-well 425. When electrons migrate, a voltage drop is induced by a resistor R1 of the N-well 425 such that the BJT Q1 and the BJT Q3 are turned on.

In an SCR having the conventional PNPN configuration, the avalanche breakdown occurs near region “B” disposed between the N-well 425 and the substrate 400. A PN junction near region “A” is a junction formed by a heavily doped P region and a lightly doped N region, but a PN junction near region “B” is a junction formed by a lightly doped N region and a lightly doped P region. In case of the former, the breakdown may occur more easily than the latter. Hence, the ESD protection circuit according to an example embodiment of the present embodiment has a low trigger voltage that is required so as to generate the avalanche breakdown.

When the BJT Q1 and the BJT Q3 are turned on by the avalanche breakdown, the BJT Q2 and the BJT Q4 are turned on. The latch-up current is generated according to the turned-on BJT Q2 and the turned-on BJT Q4, and the latch-up is terminated by termination of ESD.

When the positive ESD event occurs at the second rail 450, the operation of the ESD protection circuit may be described as follows. The P-type substrate 400 and the N-well 425 constitute a PN junction diode. When the positive ESD event occurs at the second rail 450, a forward bias is applied to the PN junction diode formed by the P-type substrate 400 and the N-well 425, so that a current generated by the positive ESD event flows from the second rail 450 to the first rail 440 through the region 434, the substrate 400, the N-well 440 and the region 424. When a negative ESD event occurs at the first rail 440, the forward bias is applied to the PN junction.

Furthermore, the negative ESD event occurs at the second rail 450, the voltage of the second rail 450 is transmitted to the substrate 400 via the region 434. Thus, a voltage difference between the gate 431 and the substrate 400 is generated such that a channel between the region 432 and the region 433 is formed. The voltage of the second rail 450 applied via the region 433 is transmitted to the region 423 through the region 432. Furthermore, the voltage of the first rail 440 is transmitted to the N-well 425 through the region 424 and the region 422. When the voltage of the first rail 440 is transmitted to the N-well 425, a strong electric field between the region 423 and the N-well 425 is generated such that the avalanche breakdown occurs. An operation after occurrence of the avalanche breakdown is substantially the same as the operation in case that the positive ESD event occurs at the first rail 440.

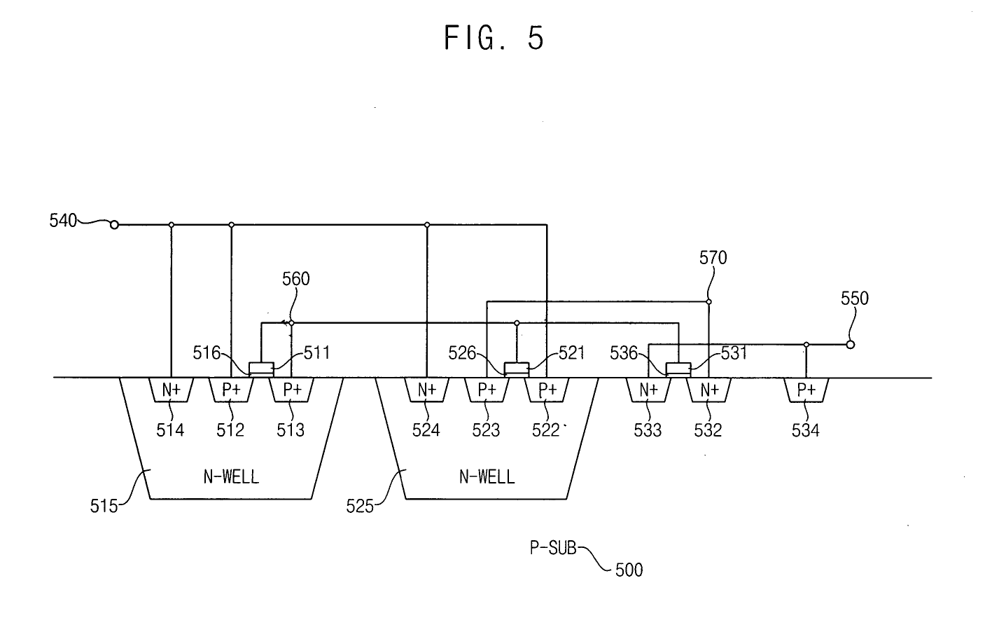

FIG. 5 is a cross sectional view illustrating an integrated circuit that implements the ESD protection circuit of FIG. 3.

Referring to FIG. 5, the ESD protection circuit connected between a first rail 540 and a second rail 550 has a CMOS configuration. More particularly, a region 524, a region 522 and a region 523 are formed in an N-well 525 provided at a surface of a substrate 500. The region 524 receives a voltage of the first rail 540. The region 522 and the region 523 are the source and drain of the first transistor in FIG. 3, respectively. Furthermore, a region 534 receiving a voltage of second rail 550, and regions 533 and 532 corresponding to the source and drain of the second transistor 330 in FIG. 3 are formed at a position that is spaced apart from the N-well 525. The region 522 is connected to the first rail 540 and the region 533 is connected to the second rail 550. Gates 521 and 531 on top of insulating layers 526 and 536 are connected to a connection node 560. The regions, rails and node are substantially the same as the corresponding parts of FIG. 4

The connection load 310 shown in FIG. 3 may be implemented as the PMOS of FIG. 5. A region 514 for receiving a voltage of second rail 550, and regions 512 and 513 corresponding to the source and drain of FIG. 3 are formed in an N-well 515 provided at the surface of the substrate 500. An insulating layer 516 is formed on the substrate 500 and between the region 512 and the region 513, and a gate 511 is formed on the insulating layer 516. The gate 511 and the region 513 are connected to a gate 521 and a gate 531 through a connection node 560. The region 512 is connected to the first rail 540.

The connection load 310 and the first transistor 320 of FIG. 3 may be implemented by the PMOSs formed in the different N-wells from each other. In addition, the connection load 310 and the first transistor 320 of FIG. 3 may be implemented by using the PMOSs that shares the N-well.

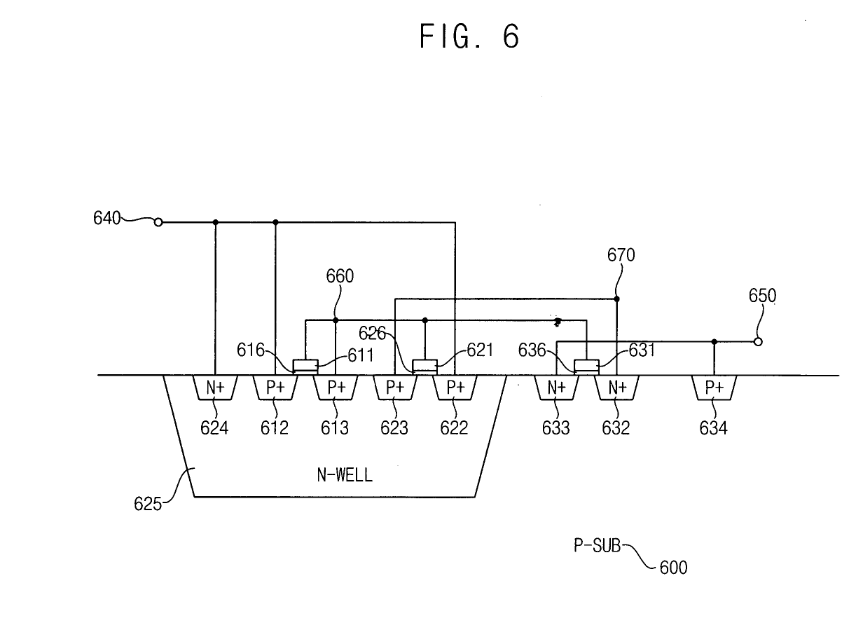

FIG. 6 is a cross sectional view illustrating an integrated circuit that implements the ESD protection circuit of FIG. 3.

Referring to FIG. 6, the ESD protection circuit connected between a first rail 640 and a second rail 650 has a CMOS configuration. More particularly, a region 624, a region 622, a region 623, a region 612 and a region 613 are formed in an N-well 625 formed at a surface of a substrate 600. The region 624 receives a voltage of the first rail 640. The region 622 and the region 623 are the source and drain of the first transistor in FIG. 3, respectively. The region 612 and the region 613 correspond to the source and the drain of the connection load 310 in FIG. 3. Furthermore, a region 634 for receiving a voltage of the second rail 650, and regions 632 and 633 respectively corresponding to the source and drain of the second transistor 330 in FIG. 3 are formed at a position spaced apart from the N-well 625. The region 612 and the region 622 are connected to the first rail 640, and the region 633 is connected to the second rail 650. The region 623 and the region 633 are connected to a connection node 670. Gates 611, 621 and 631 formed on the insulating layers 616, 626 and 636 are connected to a connection node 660.

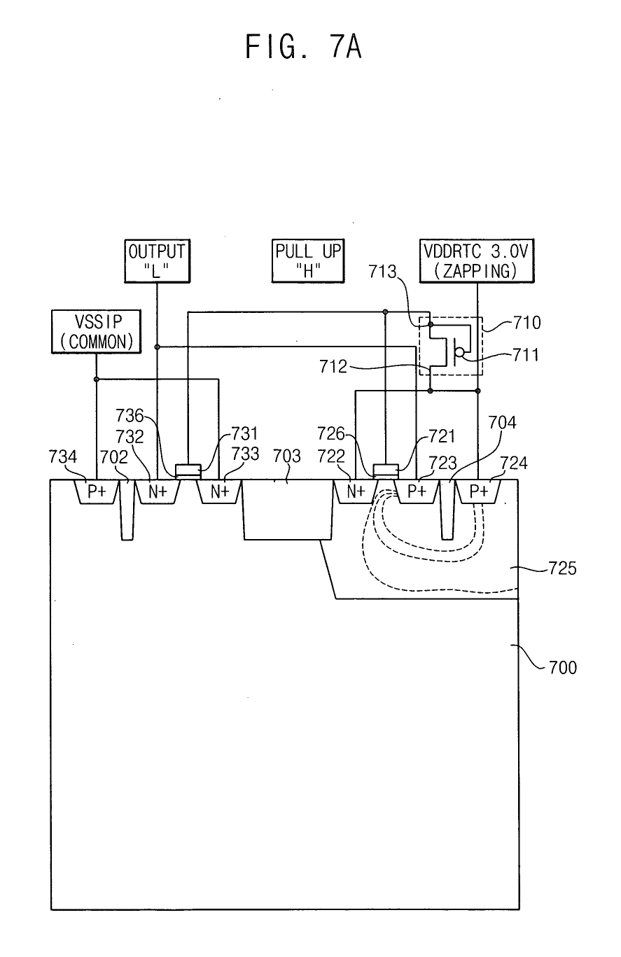

FIG. 7A and FIG. 7B are schematic views illustrating a simulation result of the operation of the ESD protection circuit shown in FIG. 3.

Referring to FIG. 7A and FIG. 7B, regions 722, 723, 724, 732, 733 and 723, an N-well 725, insulating layers 736 and 726, gates 721 and 731, and a connection load 710 are substantially the same as the corresponding parts shown in FIG. 4. Shallow Trench Isolation (STI) layers 702 and 703 are formed so as to minimize interference between transistors. In FIG. 7A, when 3.0 volts are applied to a Vdd terminal, a current generated by an avalanche breakdown flows through the N-well 725. Referring to FIG. 7B, a latch-up current is generated by the current of the avalanche breakdown.

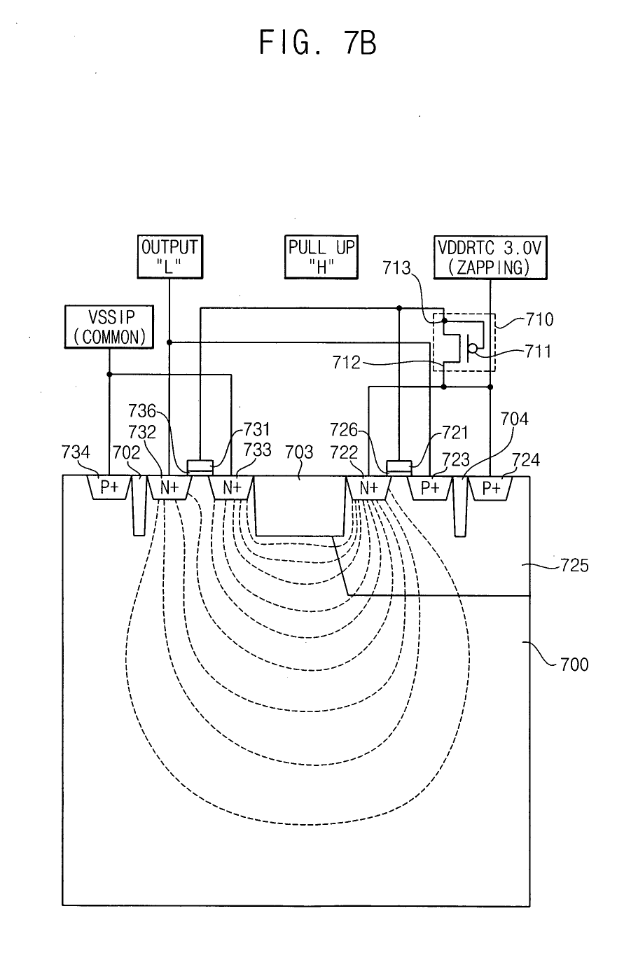

FIG. 8 is a circuit diagram of an ESD protection circuit according to another embodiment of the present invention.

Referring to FIG. 8, the ESD protection circuit is connected between a first rail 840 and a second rail 850, and has a connection load 810 and two transistors 820 and 830.

The first rail 840 and the second rail 850 may be a Vdd pad or a Vss pad that supplies a source voltage to an integrated circuit such as a memory circuit, a microprocessor or a logic circuit, or alternatively may be a data in/out pad, which are easily damaged by an ESD.

The first transistor 820 and the second transistor 830 constitute a CMOS inverter. Namely, a source of the first transistor 820 is connected to the first rail 840, and a source of the second transistor 830 is connected to the second rail 850. Drains 821 and 831 of the transistors 820 and 830 are connected to each other and gates 821 and 831 of the transistors 820 and 830 are connected to each other.

The connection load 810 transmits a voltage of the second rail 850 to a connection node 860 of the gates 821 and 831. Although the connection load 810 may be configured as a resistor, CDM characteristics are enhanced in case that the connection load 810 is configured as a MOS. The connection load 810 shown in FIG. 8 is a diode-connected NMOS transistor such that a source 812 of the connection load 810 is connected to the second load 840, and a gate 811 and a drain 813 are connected to the gates 821 and 831 of the transistors 820 and 830.

The first and second transistors 820 and 830 shown in FIG. 8 may be implemented in substantially the same manner as those of FIG. 5 and FIG. 6, and the connection load 810 may be implemented as regions heavily doped with N-type dopants, an insulating layer and a gate.

To describe an operation of the ESD protection circuit shown in FIG. 8, the first rail 840 and the second rail 850 are assumed to be a Vdd pad and a Vss pad supplying a source voltage to an integrated circuit, respectively. When the normal Vdd and Vss are supplied to the first rail 840 and the second rail 850, respectively, the connection load 810 is turned on such that the connection node 860 is pulled-down as a low level. When the connection node 860 has a low level, the first transistor 820 is turned on and the second transistor 830 is turned off, so that the connection node 870 has a high level. Furthermore, due to the turned-off second transistor 830, current path between the first rail 340 and the second rail 350 is cut off. Namely, when normal source voltage is supplied to the first rail 840 and the second rail 850, the ESD protection circuit does not operate.

When a negative ESD event occurs at the second rail 850, the operation of the ESD protection circuit is described as follows.

When the negative voltage is applied to the second rail 850, the connection node 860 has a low level owing to the turned-on connection load 810. In case that the connection node 860 has a low level, the first transistor 820 is turned on and the connection node 870 has a high level. Thus, a high voltage is applied between the drain and the source of the second transistor 830, so that the avalanche breakdown occurs. Furthermore, when the first transistor 820 and the second transistor 830 are formed on a substrate such that two transistors 820 and 830 have the configuration of the CMOS inverter, a parasitic BJT is formed. The parasitic BJTs of the CMOS inverter have substantially the same structure as an SCR, which is described in connection with FIG. 4. A current generated from the second transistor 830 according to the avalanche breakdown flows through a base of the SCR that has the parasitic BJTs and has a PNPN structure, so that a latch-up occurs in the ESD protection circuit. The latch-up is terminated when the ESD occurs. When a positive ESD event occurs at the first rail 840, the avalanche breakdown occurs at the second transistor 830 such that the SCR having the parasitic BJTs is latched-up.

When the positive ESD event occurs at the second rail 850 or the negative ESD event occurs at the first rail 840, a forward bias is applied to a parasitic diode and the ESD is performed by a forward current flowing through the parasitic diode.

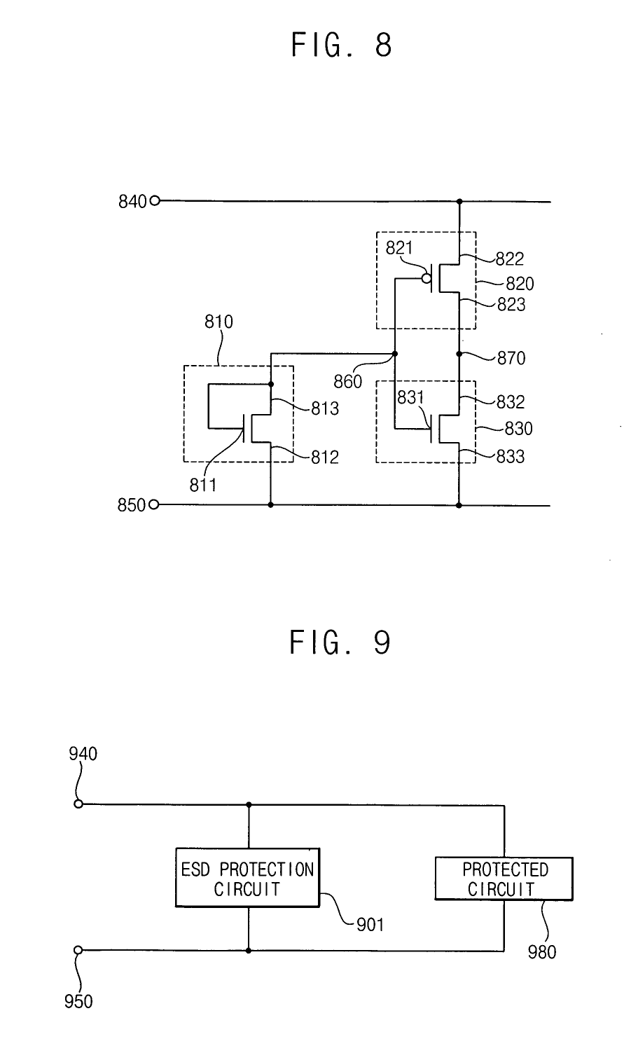

FIG. 9 is a block diagram illustrating an integrated circuit protected by an ESD protection circuit according to an example embodiment of the present invention.

Referring to FIG. 9, the ESD protection circuit 901 is connected between a first rail 940 and a second rail 950 in parallel with a protected circuit 980. For example, the first rail 940 may be a Vdd pad and the second rail 950 may be a Vss pad. When normal Vdd and Vss are supplied, the ESD circuit 901 does not operate. However, when an ESD event occurs, the ESD protection circuit 901 operates such that the ESD protection circuit 901 prevents the protected circuit 980 from being damaged. The ESD protection circuit 901 may be implemented by any circuit described at FIG. 3 through FIG. 8.

Furthermore, the first rail 940 or the second rail 950 may be a data node for receiving the predetermined data signal. In this case, when the ESD event occurs, the protected circuit 980 is protected from damage due to the ESD event. Furthermore, a plurality of ESD protection circuits is embedded in one chip. That is, the embodiments described above are intended not to limit the scope of the present invention, but to illustrate the present invention.

Hereinbefore, the ESD protection circuit or the integrated circuit having the ESD protection circuit is formed on the P-type substrate. However, the ESD protection circuit or the integrated circuit may be formed on an N-type substrate.

According to the example embodiments of the present invention, the ESD protection circuit may have a low trigger voltage. Furthermore, the ESD protection circuit has the CMOS inverter structure such that the ESD protection circuit has robust characteristics for the latch-up.

According to the example embodiments of the present invention, the ESD protection circuit having the low trigger voltage and the robust characteristics for the latch-up may be embedded in the integrated circuit such that the integrated circuit may be prevented from damage due to the ESD event.

While the example embodiments of the present invention and their advantages have been described in detail, it should be understood that various changes, substitutions and alterations may be made herein without departing from the scope of the invention.

What is claimed is:

1. An electrostatic discharge (ESD) protection circuit coupled between a first rail and a second rail, the ESD protection circuit comprising:
a substrate lightly doped with a first impurity of a first conduction type;
a first region lightly doped with a second impurity of a second conduction type, and formed at a first surface portion of the substrate;
a second region heavily doped with a third impurity of the second conduction type, formed at a second surface portion in the first region, and coupled to the first rail;
a third region heavily doped with a fourth impurity of the first conduction type, formed at a third surface portion in the first region, and spaced apart from the second region;
a fourth region heavily doped with the fourth impurity of the first conduction type, formed at a fourth surface portion in the first region, spaced apart from the third region, and coupled to the first rail;
a fifth region heavily doped with a fifth impurity of the second conduction type, formed at a fifth surface portion of the substrate, spaced apart from the first region, and coupled to the second rail;
a sixth region heavily doped with the fifth impurity of the second conduction type, formed at a sixth surface portion of the substrate, spaced apart from the fifth region, and coupled to the third region;
a seventh region heavily doped with a sixth impurity of the first conduction type, formed at a seventh surface portion of the substrate, spaced apart from the sixth region, and coupled to the second node;
a first insulating layer formed on a surface of the substrate between the third region and the fourth region;
a second insulating layer formed on the surface of the surface between the fifth region and the sixth region;
a first gate formed on the first insulating layer;
a second gate formed on the second insulating layer, and coupled to the first gate; and
a connection load having a first terminal coupled to the first rail and a second terminal coupled to the first gate.

2. The ESD protection circuit of claim 1, wherein the first conduction type is a P-type and the second conduction type is an N-type.

3. The ESD protection circuit of claim 1, wherein the connection load is a PMOS transistor, the first terminal of the connection load is a source, the second terminal of the connection load is a drain, and a gate is connected to the drain.

4. An ESD protection circuit coupled between a first rail and a second rail, the ESD protection circuit comprising:
a substrate lightly doped with a first impurity of a first conduction type;
a first region lightly doped with a second impurity of a second conduction type, and formed at a first surface portion of the substrate;
a second region heavily doped with a third impurity of the second conduction type, formed at a second surface portion in the first region, and coupled to the first rail;
a third region heavily doped with a fourth impurity of the first conduction type, formed at a third surface portion in the first region, and spaced apart from the second region;
a fourth region heavily doped with the fourth impurity of the first conduction type, formed at a fourth surface portion in the first region, spaced apart from the third region, and coupled to the first rail;
a fifth region heavily doped with a fifth impurity of the second conduction type, formed at a fifth surface portion of the substrate, spaced apart from the first region, and coupled to the second rail;
a sixth region heavily doped with the fifth impurity of the second conduction type, formed at a sixth surface portion of the substrate, spaced apart from the fifth region, and coupled to the third region;
a seventh region heavily doped with a sixth impurity of the first conduction type, formed at a seventh surface portion of the substrate, spaced apart from the sixth region, and coupled to the second rail;
a first insulating layer formed on a surface of the substrate between the third region and the fourth region;
a second insulating layer formed on the surface of the substrate between the fifth region and the sixth region;
a first gate formed on the first insulating layer;
a second gate formed on the second insulating layer, and coupled to the first gate; and
a connection load having a first terminal coupled to the second rail and a second terminal coupled to the first gate.

5. The ESD protection circuit of claim 4, wherein the first conduction type is a P-type and the second conduction type is an N-type.

6. The ESD protection circuit of claim 4, wherein the connection load is a NMOS transistor, the first terminal of the connection load is a source, the second terminal of the connection load is a drain, and a gate is connected to the drain.

7. An integrated circuit comprising:
a protected circuit;
a first rail coupled to a first terminal of the protected circuit;
a second rail coupled to a second terminal of the protected circuit;
a substrate lightly doped with a first impurity of a first conduction type;
a first region lightly doped with a second impurity of a second conduction type, and formed at a first surface portion of the substrate;
a second region heavily doped with a third impurity of the second conduction type, formed at a second surface portion in the first region, and coupled to the first rail;
a third region heavily doped with a fourth impurity of the first conduction type, formed at a third surface portion in the first region, and spaced apart from the second region;
a fourth region heavily doped with the fourth impurity of the first conduction type, formed at a fourth surface portion in the first region, spaced apart from the third region, and coupled to the first rail;
a fifth region heavily doped with a fifth impurity of the second conduction type, formed at a fifth surface portion of the substrate, spaced apart from the first region, and coupled to the second rail;
a sixth region heavily doped with the fifth impurity of the second conduction type, formed at a sixth surface portion of the substrate, spaced apart from the fifth region, and coupled to the third region;
a seventh region heavily doped with a sixth impurity of the first conduction type, formed at a seventh surface portion of the substrate, spaced apart from the sixth region, and coupled to the second rail;
a first insulating layer formed on a surface of the substrate between the third region and the fourth region;
a second insulating layer formed on the surface of the substrate between the fifth region and the sixth region;
a first gate formed on the first insulating layer;
a second gate formed on the second insulating layer, and coupled to the first gate; and
a connection load having a first terminal coupled to the first rail and a second terminal coupled to the first gate.

8. The integrated circuit of claim 7, wherein the first conduction type is a P-type and the second conduction type is an N-type.

9. The integrated circuit of claim 7, wherein the connection load is a PMOS transistor, the first terminal of the connection load is a source, the second terminal of the connection load is a drain, and a gate is connected to the drain.

10. An integrated circuit comprising:
a protected circuit;
a first rail coupled to a first terminal of the protected circuit;
a second rail coupled to a second terminal of the protected circuit;
a substrate lightly doped with a first impurity of a first conduction type;
a first region lightly doped with a second impurity of a second conduction type, and formed at a first surface portion of the substrate;
a second region heavily doped with a third impurity of the second conduction type, formed at a second surface portion in the first region, and coupled to the first rail;
a third region heavily doped with a fourth impurity of the first conduction type, formed at a third surface portion in the first region, and spaced apart from the second region;
a fourth region heavily doped with the fourth impurity of the first conduction type, formed at a fourth surface portion in the first region, spaced apart from the third region, and coupled to the first rail;
a fifth region heavily doped with a fifth impurity of the second conduction type, formed at a fifth surface portion of the substrate, and coupled to the second rail;
a sixth region heavily doped with the fifth impurity of the second conduction type, formed at a sixth surface portion of the substrate, spaced apart from the fifth region, and coupled to the third region;
a seventh region heavily doped with a sixth impurity of the first conduction type, formed at a seventh surface portion of the substrate, spaced apart from the sixth region, and coupled to the second rail;
a first insulating layer formed on a surface of the substrate between the third region and the fourth region;
a second insulating layer formed on the surface of the substrate between the fifth region and the sixth region;
a first gate formed on the first insulating layer;
a second gate formed on the second insulating layer, and coupled to the first gate; and
a connection load having a first terminal coupled to the second rail and a second terminal coupled to the first gate.

11. The integrated circuit of claim 10, wherein the first conduction type is a P-type and the second conduction type is an N-type.

12. The integrated circuit of claim 10, wherein the connection load is a NMOS transistor, the first terminal of the connection load is a source, the second terminal of the connection load is a drain, and a gate is connected to the drain.

13. An ESD protection circuit coupled between a first rail and a second rail, the ESD protection circuit comprising:
a first transistor of a first type, the first transistor having a source coupled to the first rail;
a second transistor of a second type, the second transistor having a source coupled to the second rail, a drain coupled to a drain of the first transistor, and a gate coupled to a gate of the first transistor; and
a connection load having a first terminal coupled to the first rail and a second terminal coupled to the gate of the first transistor.

14. The ESD protection circuit of claim 13, wherein the first type is a PMOS-type and the second type is an NMOS-type.

15. The ESD protection circuit of claim 13, wherein the connection load is a PMOS transistor, the first terminal of the connection load is a source, the second terminal of the connection load is a drain, and a gate is connected to the drain.

16. The ESD protection circuit of claim 13, wherein the second transistor is turned on in response to a voltage applied to the first rail so that a voltage of the drain of the first transistor is substantially the same as a voltage of the second rail.

17. The ESD protection circuit of claim 16, wherein the first transistor generates a current due to an avalanche breakdown when the second transistor is turned on so that a silicon controlled rectifier (SCR) is latched up due to a parasitic bipolar junction transistor (BJT) of the first and second transistors.

18. An ESD protection circuit coupled to a first rail and a second rail, comprising:
a first transistor of a first type, the first transistor having a source coupled to the first rail;
a second transistor of a second type, the second transistor having a source coupled to the second rail, a drain coupled to a drain of the first transistor, and a gate coupled to a gate of the first transistor; and
a connection load having a first terminal coupled to the second rail and a second terminal coupled to the gate of the second transistor.

19. The ESD protection circuit of claim 18, wherein the first type is a PMOS-type and the second type is an NMOS-type.

20. The ESD protection circuit of claim 18, wherein the connection load is a NMOS transistor, the first terminal of the connection load is a source, the second terminal of the connection load is a drain, and a gate is connected to the drain.

21. The ESD protection circuit of claim 18, wherein the first transistor is turned on in response to a voltage applied to the first rail so that a voltage of the drain of the second transistor is substantially the same as a voltage of the first rail.

22. The ESD protection circuit of claim 21, wherein the second transistor generates a current due to an avalanche breakdown when the first transistor is turned on so that an SCR is latched up due to a parasitic BJT of the first and second transistors.

23. An integrated circuit comprising:
a protected circuit;
a first rail coupled to a first terminal of the protected circuit;
a second rail coupled to a second terminal of the protected circuit;
a first transistor of a first type, the first transistor having a source coupled to the first rail;
a second transistor of a second type, the first transistor having a source coupled to the second rail, a drain coupled to a drain of the first transistor, and a gate coupled to a gate of the first transistor; and
a connection load having a first terminal coupled to the first rail and a second terminal coupled to the gate of the first transistor.

24. The integrated circuit of claim 23, wherein the first type is a PMOS-type and the second type is an NMOS-type.

25. The integrated circuit of claim 23, wherein the connection load is a PMOS transistor, the first terminal of the connection load is a source, the second terminal of the connection load is a drain, and a gate is connected to the drain.

26. The integrated circuit of claim 23, wherein the second transistor is turned on in response to a voltage applied to the first rail so that a voltage of the drain of the first transistor is substantially the same as a voltage of the second rail.

27. The integrated circuit of claim 26, wherein the first transistor generates a current due to an avalanche breakdown when the second transistor is turned on so that an SCR is latched up due to a parasitic BJT of the first and second transistors.

28. An integrated circuit comprising:
a protected circuit;
a first rail coupled to a first terminal of the protected circuit;
a second rail coupled to a second terminal of the protected circuit;
a first transistor of a first type, the first transistor having a source coupled to the first rail;
a second transistor of a second type, the second transistor having a source coupled to the second rail, a drain coupled to a drain of the first transistor, and a gate coupled to a gate of the first transistor; and
a connection load having a first terminal coupled to the second rail and a second terminal coupled to the gate of the first transistor.

29. The integrated circuit of claim 28, wherein the first type is a PMOS-type and the second type is an NMOS-type.

30. The integrated circuit of claim 28, wherein the connection load is a NMOS transistor, the first terminal of the connection load is a source, the second terminal of the connection load is a drain, and a gate is connected to the drain.

31. The integrated circuit of claim 28, wherein the first transistor is turned on in response to a voltage applied to the second rail so that a voltage of the drain of the second transistor is substantially the same as a voltage of the first rail.

32. The integrated circuit of claim 31, wherein the second transistor generates a current due to an avalanche breakdown when the first transistor is turned on so that an SCR is latched up due to a parasitic BJT of the first and second transistors.
